(19) United States
(12) Patent Application Publication
(10) Pub. No.: US 2018/0047588 A1
(43) Pub. Date: Feb. 15, 2018

(54) LEAD CARRIER STRUCTURE AND PACKAGES FORMED THEREFROM WITHOUT DIE ATTACH PADS

(71) Applicant: EOPLEX LIMITED, Hong Kong (CN)

(72) Inventor: Philip E ROGREN, San Jose, CA (US)

(73) Assignee: EOPLEX LIMITED, Hong Kong (CN)

(21) Appl. No.: 15/542,401

(22) PCT Filed: May 4, 2016
(86) PCT No.: PCT/US2016/030775

§ 371 Date: Jul. 7, 2017

Related U.S. Application Data
(60) Provisional application No. 62/156,488, filed on May 4, 2015.
(60) Provisional application No. 62/156,983, filed on May 5, 2015.

(51) Int. Cl. H01L 21/48; H01L 23/31; H01L 21/56; H01L 23/495; H01L 23/00

(52) U.S. Cl. CPC H01L 21/4821; H01L 23/495; H01L 23/49579; H01L 23/49544; H01L 24/85; H01L 24/97; H01L 21/568; H01L 24/05; H01L 23/3107; H01L 24/48; H01L 2224/04026; H01L 2224/05639; H01L 2224/05644; H01L 2224/05669; H01L 2224/48091; H01L 2224/48106; H01L 2224/48247; H01L 2224/85005; H01L 2224/85439; H01L 2224/85539; H01L 2224/97; H01L 2924/18165; H01L 2924/386

(57) ABSTRACT

A lead carrier includes a continuous sheet of mold compound having a top side and an opposing back side, and forms an array of package sites corresponding to semiconductor packages. Each package site when fabricated includes a semiconductor die having a top side, and an opposing treated base exposed at the back side of the continuous sheet of mold compound; a set of terminal pads, each having a top side and an opposing back side exposed at the back side of the continuous sheet of mold compound; a plurality of wire bonds formed between a set of input/output junctions on the top side of the semiconductor die and the top side of each terminal pad; and hardened mold compound encapsulating the semiconductor die, the set of terminal pads, and the plurality of wire bonds. Each package site excludes a die attach pad to which the semiconductor die is fixed.

### TECHNICAL FIELD

Aspects of the present disclosure relate to integrated circuit chip lead carrier packages that enable effective interconnection of an integrated circuit chip with an electrical circuit or system. More particularly, the present disclosure relates to lead frames and other lead carriers manufactured as an array of multiple package sites within a common assembly before and during combination with integrated circuits, attachment of wire bonds thereto, and encapsulation of the common assembly and the integrated circuits carried thereby within non-conductive material, before singulation or isolation into individual packages, e.g., for use upon an electronics system board such as a printed circuit board.

### BACKGROUND

The demand for smaller and more capable, portable electronic systems, combined with the increased level of integration in today's semiconductor circuits/devices is driving a need for smaller semiconductor packages with greater numbers of input/output terminals. At the same time, there is relentless pressure to reduce the cost of all components of consumer electronic systems, including semiconductor packages. The quad flat no lead (“QFN”) semiconductor package family is among the smallest and most cost effective of all semiconductor package types, but when fabricated with conventional techniques and materials, has significant limitations. For instance, with conventional QFN technology the number of I/O terminals and the electrical performance that the technology can support is undesirably limited.

FIGS. 1-5 are schematic illustrations showing aspects of a conventional QFN lead frame 1 (FIGS. 1 and 2) and corresponding conventional QFN packages P (FIGS. 3-5) that were manufactured or assembled thereon. Packages P are conventionally assembled on a common area array lead frame 1 that has been etched from a planar sheet of conductive material such as copper to form an array of distinct die attach pads 2 as well as a plurality of wire bond pads 4 corresponding each die attach pad 2. Any given die attach pad 2 and its corresponding wire bond pads 4 form a package site, i.e., a site at which a package P is manufactured or assembled. Conventionally, each package site corresponds to or includes a die attach pad 2 surrounded by one or two rows of wire bond pads 4. A given lead frame 1 can contain from tens to thousands of package sites.

For any given package P, its die attach pad 2 provides a platform that facilitates fixing a semiconductor die or integrated circuit chip 7 within the package P; and the wire bond pads 4 provide terminals within the package P that can be electrically connected to input/output terminals of the integrated circuit chip 7 by way of wire bonds 8, in a manner readily understood by individuals having ordinary skill in the relevant art. The wire bond pads 4 also provide a means of electrically coupling the integrated circuit chip 7 to an electronic system board such as a printed circuit board through a solder joint 5 on the surface of the package P opposite to that of the surface corresponding to the wire bonds 8, as also readily understood by individuals having ordinary skill in the relevant art.

As a result of the structure of the lead frame 1 and the nature of the process by which packages P are assembled thereon, all of the components of each package P are attached and electrically coupled to the common lead frame 1. More particularly, all of the components of each package P assembled on a given lead frame 1 are attached to the lead frame 1 by conductive links (e.g., copper lines) commonly referred to as tie bars 3 to maintain the position of the components of each package P relative to the lead frame 1, and to provide an electrical connection to all such components to facilitate electroplating of bonding and soldering surfaces corresponding to each package P.

Still more particularly, the tie bars 3 electrically short the components of each package P assembled on the lead frame 1 to common shorting structures 6 (e.g., copper rails) of the lead frame 1. The shorting structures 6 surround each package site, and are organized in a predetermined pattern, such as an x-y grid pattern. The tie bars 3 must be designed such that they can be disconnected from the shorting structures 6 during singulation of individual packages P from the lead frame 1, leaving the die attach pad 2 and corresponding wire bond pads 4 of any given package P electrically isolated from those of each other package P, as further detailed below.

The requirement that all electrical components of a package P be connected to the lead frame 1 by a metal structure severely limits the number of leads that can be implemented in any given package P. For instance, at a given package site, wire bond pads 4 can be provided in multiple rows surrounding the die attach pad 2, with each row being a different distance away from the die attach pad 2. However, the tie bars 3 must be routed between the wire bond pads 4 such that the tie bars 3 extend to the shorting structures 6 beyond the footprint of the package P (corresponding to line X in FIG. 2). The minimum scale of these tie bars 3 is such that only one tie bar 3 can be routed between two adjacent wire bond pads 4. Thus, only two rows of wire bond pads 4 are implemented in conventional QFN lead frames 1. Because of the current relationship between die size and lead count, conventional QFN packages are limited to around one hundred terminals, with a majority of packages P having no more than about sixty terminals. This limitation unfortunately prevents the use of conventional QFN packages P with many types integrated circuit chips 7 that would otherwise benefit from the small size and generally low cost of QFN technology.

As shown in FIGS. 1 and 2, the entire lead frame 1 is mounted on a high temperature molding tape T, such that the back surface of the lead frame 1, the back surfaces of each die attach pad 2, and the back surfaces of each wire bond pad 4 reside on an upper surface of the molding tape T. After the integrated circuit chips 7 have been mounted to the die attach pads 2 and wire bonds 8 have been formed between particular input/output pads of the integrated circuit chips 7 and corresponding wire bond pads 4 at each package site, an epoxy mold compound 9 is applied to the entire lead frame 1 and the structures carried thereby, such as by way of a high temperature transfer molding process, during which the epoxy mold compound 9 encapsulates the lead frame 1 and the structures carried thereby above the upper surface of the molding tape T to create an assembled lead frame 1. The presence of the molding tape T prevents the molding compound 9 from encapsulating the undersides of the die attach pads 2 and the wire bond pads 4. Consequently, after the mold compound 9 has hardened, the molding tape T can be peeled away such that solder joints 5 (FIG. 5) corresponding to the undersides of the die attach pad 2 and wire bond pads 4 of each package P are exposed on the underside of the assembled lead frame 1. The interface between the molding tape T and any given package P thus defines the backplane of the package P.

Because the molding tape T must withstand high temperature wire bonding and molding processes without adverse effects, the molding tape T is relatively expensive. Furthermore, the process of applying the molding tape T, removing the molding tape T, and removing adhesive residues can add significant cost to processing each lead frame 1. Moreover, the molding tape T is not reusable, adding to expense and produced waste.

After the molding process, the assembled lead frame 1 contains multiple structurally and electrically interconnected packages P. Each package P in the assembled lead frame 1 can be defined to have an initial footprint that extends to the midpoints of the shorting structures 6 that surround the package P, such that each package P in the assembled lead frame 1 is structurally joined or connected to adjacent packages P. The assembled lead frame 1 must therefore be divided or cut by way of a singulation process, such as a sawing process, to produce individual electrically isolated packages P. During the singulation process, portions of the mold compound 9 and the connections between the shorting structures 6 and the tie bars 3 are destroyed, for instance, sawn away, e.g., along line X of FIG. 2. As a result of the singulation process, each package P typically has a final footprint that extends close or very close to the shorting structures 6 that surround(ed) the package P.

The most common method of singulation of the individual packages P from the lead frame 1 is by sawing (e.g., along line X of FIG. 2). Because the saw must remove all of the shorting structures 6 just outside the package P outline, in addition to cutting the epoxy mold compound 9, the process is substantially slower and blade life considerably shorter, compared to if only mold compound 9 were cut. Because the shorting structures 6 are not removed until the singulation process, this means that the packaged integrated circuit chips 7 cannot be tested until after singulation. Handling thousands of tiny packages P, and assuring each is presented to the tester in the correct orientation is much more expensive than being able to test the entire assembled lead frame 1 with each package P having a known location and orientation.

Another singulation process, known as punch singulation, to some extent addresses the problem associated with saw singulation and allows testing in the assembled lead frame 1, but substantially increases cost by cutting utilization of the lead frame 1 to less than fifty percent of that of a saw singulated lead frame 1. Punch singulation also imposes a requirement for dedicated mold tooling for every basic lead frame design. Standard lead frames 1 designed for saw singulation use a single mold cap for all lead frames 1 of the same dimensions.

After either saw singulation or punch singulation, the tie bars 3 remain in each final or completed package P, and these tie bars 3 remain exposed at the edge of each package P in a manner shown in FIGS. 3-5. The tie bars 3 in the completed packages P represent both capacitive and inductive parasitic elements that cannot be removed. These now superfluous pieces of metal can significantly impact the performance of the completed package P, precluding the use of QFN packages P for many high performance integrated circuit chips 7 and applications. Furthermore, the cost of this potentially rather valuable superfluous metal can be substantial and is wasted by conventional QFN manufacturing processes.

Several concepts have been advanced for QFN type substrates that eliminate the limitations of conventional etched lead frame based processes described above. Among these is a process that deposits an array of package components on a sacrificial carrier by electroplating. The carrier is first patterned with plating resist and the carrier, usually stainless steel, is slightly etched to enhance adhesion. The patterned carrier is then plated with gold and palladium to create an adhesion/barrier layer, then plated with Ni to around sixty microns thick to form Ni bumps. The top of the Ni bumps are finished with a layer of electroplated Ag to facilitate wire bonding. After integrated circuit/wire bond assembly and molding, the carrier is peeled away to leave a sheet of packaged dies that can be tested in sheet form, and singulated at higher rates and yields than with conventional lead frames. This electroplated approach eliminates the issues associated with tie bars 3 remaining within the package P, and allows for very fine features. Such an electroplating process, however, is very expensive compared to standard etched lead frame processes.

Another approach is a modification of the etched lead frame process, wherein a front side pattern is etched to about half the thickness of the lead frame, and the back side of the lead frame is left intact, until after the molding process is complete. Once molding is complete, the back side pattern is printed and the lead frame is further etched to remove all of the metal except for the back side portion of the wire bond pads 4 and die attach pads 2. This double etch process also eliminates all of the issues associated with connective metal structures, i.e., tie bars 3, remaining within the package P. While the cost of the double etched lead frame is less than the electroplated version, it is still more expensive than standard etched lead frame processes, and the etching and plating processes are environmentally undesirable.

One failure mode for a lead frame packaged integrated circuit is for the wire bond pads 4 to become disconnected from wire bonds 8 coupled thereto, especially when a shock load is experienced by the package P (such as when an electronic device within the package P is dropped and hits a hard surface). The wire bond pad 4 can remain mounted to a printed circuit board or other electronic system board, while separating slightly from the surrounding epoxy mold compound 9, allowing the wire bond 8 to be severed from the wire bond pad 4. Accordingly, a need exists for a lead carrier package which better holds the wire bond pads 4 within the entire package, especially when shock loads are experienced.

### SUMMARY

In accordance with embodiments of the present disclosure, a lead carrier or lead carrier structure includes an array of individual package sites therein, where the array of separate package sites correspond to and can be separated into multiple individual packages (e.g., QFN packages in accordance with several embodiments of the present disclosure). The lead carrier is produced by first providing a temporary support layer or temporary layer formed of a high temperature resistant material, such as stainless steel. A sinterable material, typically originating as or including silver powder, is placed or formed upon the temporary layer in a predetermined structural pattern. The stainless steel or other material forming the temporary layer supports the sinterable material while it is heated to a sintering temperature.

The sintered material is located upon the temporary layer as distinct or separate structures that are electrically isolated from each other, other than being electrically coupled to each other through the temporary layer itself, in the form of terminal pads corresponding to die attach areas or regions of the temporary layer. Embodiments in accordance with the present disclosure eliminate the requirement for a structure such as a die attach pad to be present on the temporary layer specifically for the purpose of receiving and holding a semiconductor device or die such as an integrated circuit chip or integrated circuit, because such a semiconductor device can be temporarily affixed, e.g., with an adhesive, to the temporary layer.

Thus, lead carriers and packages obtained therefrom in accordance with embodiments of the present disclosure eliminate the need for die attach pads, which can provide several advantages. For instance, in semiconductor devices which by their nature dissipate large amounts of power into a package, providing the package such that the back side of the die can be connected directly to the copper traces of a printed circuit board substantially reduces the thermal resistance between the die and the printed circuit board, thereby greatly reducing the maximum temperature generated within the package. Further, since there is no die attach pad, and thus no corresponding die attach adhesive by which the die is attached to the die attach pad, there is no possibility that the die attach adhesive will reach a temperature in excess of its glass transition temperature and as a result increase even further in thermal resistance, as well as lose tight connection to the die attach pad.

Another advantage is for devices that are sensitive to thermally induced stress, such as some microelectromechanical system (MEMS) devices. In this case, eliminating the die attach pad, which exhibits high thermal expansion, eliminates the greatest source of stress from the materials in contact with the sensitive (e.g., MEMS) device. Eliminating the die attach pad also allows the package to be thinner compared to a conventional package P by the thickness of the die attach pad, typically at least 40 μm and in the case of some high power devices, by as much as 400 μm.

Eliminating the die attach pad also allows for the substitution of an inexpensive temporary adhesive for the costly silver filled epoxy used where electrical and thermal connections to the PCB are usually required. Temporarily fixing the die to the temporary layer for wire bonding and molding can be accomplished with a number of low strength adhesives that will separate from the die during a peeling operation, or will fail within the body of the adhesive leaving some adhesive on both the temporary layer and the back of the die. In some embodiments, the back of the die is coated with a material that provides only limited and controlled adhesion of the die to the adhesive used to temporarily fix the die in place, and which also acts as a pretreatment to enhance the solderability of the die. One class of materials that will work in this application includes precious metals such as gold, platinum, or silver.

Embodiments in accordance with the present disclosure are designed to provide die attach regions corresponding to predetermined spatial regions or portions of the temporary layer, rather than die attach pads. Each die attach region is configured to have at least one integrated circuit chip or other semiconductor device supported thereon. One or more terminal pads are associated with or surround each die attach region. Wire bonds can be selectively routed from the integrated circuit(s) positioned or disposed upon a given die attach region to the individual terminal pads surrounding the die attach region. Mold compound can then be applied to the entire temporary layer, which encapsulates the integrated circuits, terminal pads, and wire bonds carried by the temporary layer to thereby form an assembled lead carrier structure that includes a molded lead carrier structure that resides on the temporary layer. Only surface mount joints defining the back sides or under portions of the integrated circuit chips and the terminal pads remain unencapsulated by the mold compound, because they face and are adjacent to the temporary layer.

Once the mold compound has hardened, the temporary layer can be peeled away from the assembled lead carrier structure, yielding a stand-alone molded lead carrier structure independent of the temporary layer. The stand-alone molded lead carrier structure includes a plurality or array of package sites that extend across its surface area, where adjacent or adjoining package sites are joined together by the hardened mold compound. Each individual package site includes a top or upper surface, border, or side beneath which (i) at least one integrated circuit chip that previously resided upon a particular die attach region of the temporary layer; (ii) the terminal pads that surrounded this die attach region; and (iii) the wire bonds that were formed between the integrated circuit chip(s) and these terminal pads are embedded in the hardened mold compound. Each individual package site further includes a bottom surface, underside, or back side having exposed surface mount joints corresponding to (i) the back side(s) of the integrated circuit chip(s) contained in the package site, and (ii) the back sides of the terminal pads contained in the package site. Individual packages can be formed from the stand-alone molded lead carrier by cutting the stand-alone molded lead carrier along boundaries between the package sites (e.g., in a x-y grid pattern). An individual package can subsequently be surface mounted through its surface mount joints to an electronics system board or other support or interface, in a manner readily understood by individuals having ordinary skill in the relevant art.

In addition to the foregoing, in various embodiments each terminal pad has edges around the periphery thereof which are shaped or configured to mechanically or structurally engage with the mold compound at least somewhat to aid secure retention of the terminal pad within the mold compound. In particular, these edges can taper in an undercut or overhanging fashion, or be stepped in an undercut or overhanging fashion, or otherwise be configured so that at least a portion of each edge at an upper or top portion of a terminal pad extends further laterally than portions of each edge closer to a lower or bottom portion of the terminal pad. Thus, the mold compound, once hardened, effectively locks the terminal pads securely into the mold compound by way of engagement with the undercut or overhanging terminal pad edges. In this manner, the terminal pads resist detachment from the wire bonds and/or resist otherwise becoming detached from the mold compound, and maintain any given package as a single unitary structure.

In accordance with an aspect of the present disclosure, a lead carrier for assembling packaged semiconductor die encapsulated in a mold compound includes: a continuous sheet of mold compound having a top side and an opposing back side, the continuous sheet of mold compound comprising an array of package sites, where each package site corresponding to a semiconductor die package, and each package site when fabricated includes: a semiconductor die having a top side and an opposing treated base that is exposed at the back side of the continuous sheet of mold compound; a set of terminal pads (e.g., disposed at particular (x, y) locations of the package site, which are outside of the (x, y) locations at which the semiconductor die resides), each terminal pad having a top side and an opposing back side that is exposed at the back side of the continuous sheet of mold compound; a plurality of wire bonds formed between a set of input/output junctions on the top side of the semiconductor die and the top side of each terminal pad within the set of terminal pads; and hardened mold compound that encapsulates the semiconductor die, the set of terminal pads, and the plurality of wire bonds. Each package site excludes a die attach pad to which the semiconductor die is fixed.

The treated base of the semiconductor die can include a coating of gold, platinum, silver, and/or an alloy thereof applied to a back side of the semiconductor die. At each package site the exposed treated base of the semiconductor die and the exposed back side of each terminal pad within the set of terminal pads define surface mount junctions for the semiconductor die package corresponding to the package site.

During fabrication or assembly, the lead carrier further includes a temporary support layer that supports the continuous sheet of mold compound, the temporary support layer having a top surface against which the bottom surface of the continuous sheet of mold compound resides. At each package site, a temporary adhesive layer is disposed between the treated base of the semiconductor die and the top surface of the temporary support layer, wherein the temporary adhesive layer is removable from the treated base of the semiconductor die. The temporary adhesive layer can include or be a conventional die attach material having a higher level of adhesion to the top surface of the temporary support layer than to the treated base of the semiconductor die.

Each terminal pad includes or is a sintered material adhered to the top surface of the temporary support layer. Each terminal pad has a height and a peripheral border, wherein the peripheral border of at least one terminal pad within the set of terminal pads includes an overhang region that causes an upper portion of the terminal bad to laterally extend beyond a lower portion of the terminal pad, and wherein the overhang region interlocks with the hardened mold compound to resist downward vertical displacement of the terminal pad from the hardened mold compound.

At each package site a level of adhesion of each terminal pad to the top surface of the temporary support layer is less than a level of adhesion of the peripheral border of the terminal pad to the hardened mold compound. The temporary support layer is thus peelably removable from the continuous sheet of mold compound.

In accordance with an aspect of the present disclosure, a semiconductor die package such as a Quad Flat No Lead (QFN) package has a top side and an opposing back side and includes: a semiconductor die having a top side and an opposing treated base that is exposed at the back side of the semiconductor die package; a set of (i.e., one or more) terminal pads (e.g., disposed at particular (x, y) locations of the package, which are outside of the (x, y) locations at which the semiconductor die resides), each terminal pad having a top side and a back side that is exposed at the back side of the semiconductor die package; a plurality of wire bonds formed between input/output junctions on a top surface of the semiconductor die and top surface of each terminal pad within the set of terminal pads; and hardened mold compound that encapsulates the semiconductor die, the set of terminal pads, and the plurality of wire bonds, wherein the semiconductor die package excludes a die attach pad to which the semiconductor die of the package site is fixed.

The treated base of the semiconductor die includes a coating of gold, platinum, silver, and/or an alloy thereof applied to a back side of the semiconductor die. Each terminal pad has a height and a peripheral border, wherein the peripheral border of at least one terminal pad within the set of terminal pads includes an overhang region that causes an upper portion of the terminal bad to laterally extend beyond a lower portion of the terminal pad, and wherein the overhang region interlocks with the hardened mold compound to resist downward vertical displacement of the terminal pad from the hardened mold compound.

In accordance with an aspect of the present disclosure, a process for fabricating packaged semiconductor die by way of a lead carrier includes: providing a temporary support layer having a top side on which semiconductor die packages are to be assembled at corresponding package sites, each package site comprising a predetermined fractional area of the temporary support layer on the top side thereof, and having a die attach region therein; disposing a paste carrying a sinterable metal in a predetermined pattern on the top side of the temporary support layer; sintering the paste to form a set of terminal pads at each package site, each terminal pad having a top side and an opposing back side adhered to the temporary support layer, wherein the set of terminal pads is disposed outside of the die attach region of the package site in accordance with the predetermined pattern of the paste; at each package site, mounting a semiconductor die to the die attach region of the package site by disposing a temporary adhesive layer on the top surface of the temporary support layer in the die attach region and disposing a treated base of the semiconductor die on the temporary support layer such that the temporary adhesive layer is interposed between the treated base of the semiconductor die and the top surface of the temporary support layer; at each package site, selectively forming a plurality of wire bonds between a set of input/output terminals of a top side of the semiconductor die and top side of each terminal pad within the set of terminal pads; forming a continuous sheet of molded package sites by applying a mold compound across the package sites such that the semiconductor die, the set of terminal pads, and the plurality of wire bonds formed at each package site are encapsulated in the mold compound; peeling the temporary support layer away from the continuous sheet of molded package sites and removing the temporary adhesive layers from the treated bases of the semiconductor die of the continuous sheet of molded package sites; and separating individual package sites within the continuous sheet of molded package sites from each other to thereby form individual packages that each contain a selected semiconductor die and a selected set of terminal pads electrically coupled thereto, wherein each package includes a top side and an opposing bottom side at which the treated base of the selected semiconductor die and the bottom side of each terminal pad within the selected set of terminal pads of the package are exposed to thereby form surface mount junctions of the package.

The process further includes at each package site avoiding providing a die attach pad on which the semiconductor die of the package site is fixable. At each package site, the temporary adhesive layer can include or be a conventional die attach material having a higher level of adhesion to the top surface of the temporary support layer than to the treated base of the semiconductor die disposed at the package site.

### NON-LIMITING OBJECTS OF REPRESENTATIVE EMBODIMENTS

Accordingly, non-limiting objects of particular embodiments in accordance with the present disclosure can include one or more of the following:

One object is to provide a system for forming and testing the electrical interconnect components of a semiconductor package that allows for the implementation of a simplified QFN process to more easily produce QFN packaged semiconductor dies.

Another object is to provide a system and process for providing electrical interconnect components of semiconductor packages arrayed on a sacrificial carrier that can be peeled away after molding to yield a continuous strip of multiple semiconductor packages with terminal pads having no electrical connection between any two terminal pads, to facilitate testing of various components of a semiconductor package in a manner that enables higher electrical performance while utilizing a minimum amount of metal therein to facilitate electrical connection of a semiconductor die to an external electronic system such as a system board. In at least some embodiments, the sacrificial carrier should be recyclable or usable for other purposes after it has been peeled away.

Another object is to provide electrical interconnect components of a semiconductor package in a manner that lowers the assembly cost of the package by simplifying and eliminating steps from a standard QFN assembly process.

Another object is to provide electrical interconnect components of a semiconductor package in a manner that allows for the inclusion of more than two rows of input/output terminals and many times the number of input/output terminals than are practical with lead frame based QFN packages.

Another object is to provide electrical interconnect components of a semiconductor package in a manner that allows greater design flexibility to incorporate features, such as multiple power and ground structures and multiple die attach regions, when compared to conventional lead frame based QFN packages.

Another object is to provide a lead carrier with multiple integrated circuit mounting package sites thereon which can be manufactured in a low cost and high quality manner.

Another object is to provide a semiconductor package for electrical interconnection to adjacent components which is highly resistant to damage associated with shock loads thereto.

Another object is to provide a lead carrier with multiple integrated circuit mounting package sites which exhibits high electrical performance by minimizing excess conducting portions therein.

Another object is to provide a vehicle for manufacturing QFN or land grid array type packages that do not require a separate structure for mounting and holding the semiconductor device during the semiconductor assembly process.

Another object is to provide a semiconductor package which reduces the tendency for the thermal resistance to increase as the packaging material and a die attach epoxy heat to temperatures above the glass transition temperatures of those materials.

Another object is to provide a semiconductor package with reduced thermal resistance between the semiconductor junction and a printed circuit board (PCB).

Another object is to provide a semiconductor package which eliminates the stress, due to differential thermal expansion, induced between a die attach pad and the semiconductor die, upon heating and cooling of the package.

Other objects will become apparent from a careful reading of the detailed description, corresponding FIGs., and claims herein.

### BRIEF DESCRIPTION OF THE DRAWINGS

FIG. 1 is a perspective view of a prior art QFN lead frame of a simplified variety, illustrating prior art lead frame technology.

FIG. 2 is a perspective view of a detail portion of FIG. 1, along with dashed lines indicative of where cut lines are followed to separate individual package sites from the lead frame.

FIG. 3 is a perspective view of a prior art QFN package P showing placement of an integrated circuit chip and wire bonds and illustrating in broken lines how encapsulation material is placed relative to other conductive structures within the package P.

FIG. 4 is a perspective view similar to that which is shown in FIG. 3, but with the encapsulating mold compound in place, and with portions of the encapsulating mold compound cut away to reveal interior structures of the package P.

FIG. 5 is a perspective view similar to that which is shown in FIG. 4, but from below to illustrate solder joints available for surface mounting of the package P upon an electronic system board or other interface within an electrical system.

FIG. 6 is a perspective view of a lead carrier in accordance with an embodiment of the present disclosure having a temporary support member on which multiple distinct or separate package sites are formed.

FIG. 7 is a perspective view of a detail of a portion of the lead carrier of FIG. 6, further illustrating details of each package site before mounting of an integrated circuit or semiconductor die, attachment of wire bonds, and encapsulation within mold compound.

FIG. 8 is a perspective view of an individual package site on a lead carrier in accordance with an embodiment of the present disclosure after placement of an integrated circuit and wire bonds, and illustrating in broken lines the position of mold compound.

FIG. 9 is a perspective view similar to FIG. 8, but with the mold compound shown in place encapsulating conductive structures within a package, and with portions of the mold compound cut away to reveal interior details of the package in accordance with an embodiment of the present disclosure.

FIG. 10 is a perspective view from below of the package of FIG. 9, illustrating surface mount joints of the package in accordance with an embodiment of the present disclosure.

FIGS. 11-17 are cross sectional views showing aspects of a representative process for manufacturing a lead carrier in accordance with an embodiment of the present disclosure.

FIG. 18 is a perspective view showing portions of a lead carrier in accordance with another embodiment of the present disclosure, which includes terminal pads having one or more types of edge contours that exhibit different engagement properties with surrounding encapsulating mold compound.

FIG. 19 is a cross-sectional view illustrating the arrangement of an integrated circuit chip and its base with an adhesive layer applied thereto while the temporary support member is being removed or peeled away from the lead carrier in accordance with an embodiment of the present disclosure.

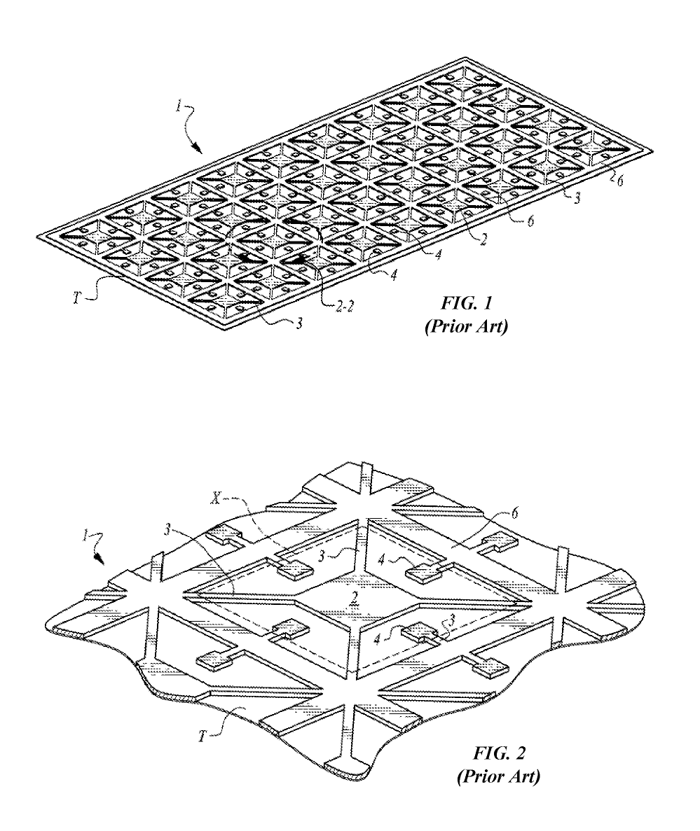

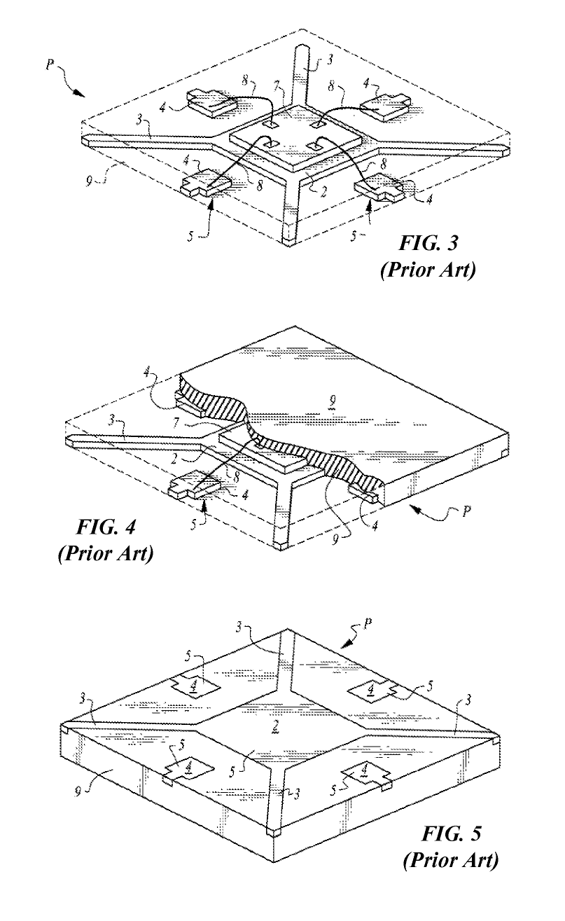

### DETAILED DESCRIPTION

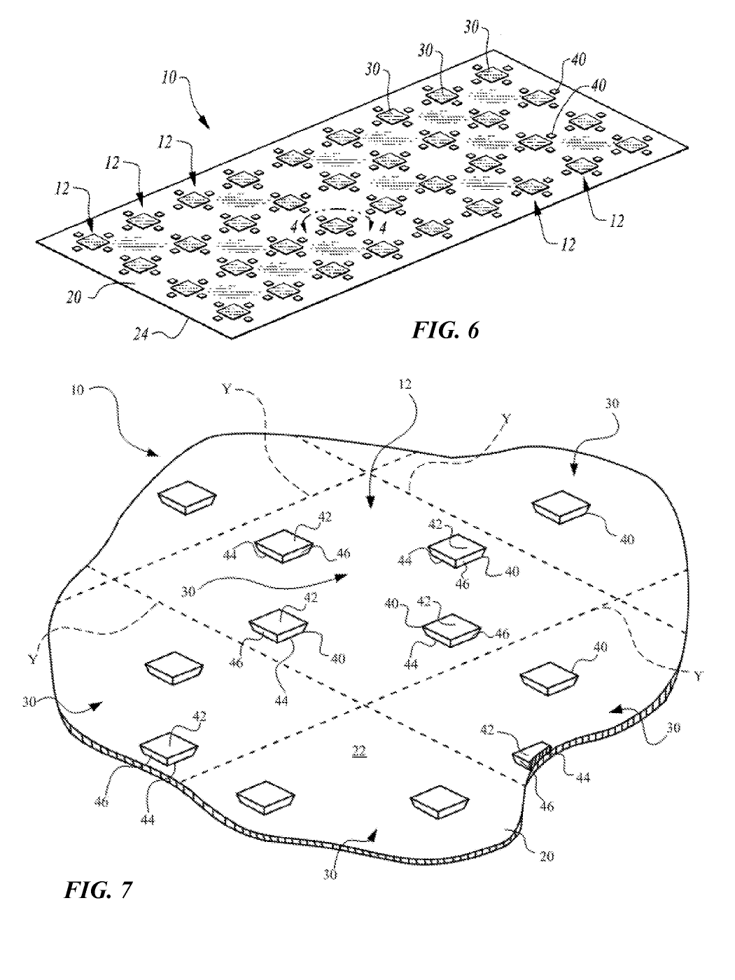

Referring to the FIGs., wherein like reference numerals represent like parts throughout, FIGS. 6 and 7 illustrate portions of a representative lead carrier structure or lead carrier 10 in accordance with an embodiment of the present disclosure, which includes a temporary support layer or member 20 that provides a plurality of package sites 12 for supporting the fabrication, assembly, or manufacture of a plurality of corresponding packages 100 such as shown in FIGS. 9 and 10 (e.g., QFN packages) thereon. Each package site 12, and hence each package 100, includes or contains at least one semiconductor die, integrated circuit chip, integrated circuit, and/or other microelectronic device 60 therein, and provides at least one and typically a plurality of input/output electrical signal transfer pathways, couplings, or connections to such device(s) 60 (e.g., up to hundreds of such pathways) as further detailed below. For purpose of brevity and to aid understanding, semiconductor die, integrated circuit chips, integrated circuits, and/or other types of microelectronic devices 60 that can be incorporated into lead carriers 10, package sites 12, and packages 100 in accordance with embodiments of the present disclosure are hereafter referred to as integrated circuit chips 60.

In various embodiments, the temporary support member 20 includes or is a thin planar high temperature resistant material, such as stainless steel. The temporary support member 20 includes a top surface 22 upon which other portions of the lead carrier 10 are fabricated, assembled, manufactured, as further detailed below. An edge 24 of the temporary support member 20 defines a perimeter of the temporary support member 20. In this representative embodiment, the temporary support member 20 is generally rectangular, although the temporary support member 20 can take other shapes in other embodiments.

The top surface 22 of the temporary support member 20 supports the plurality of package sites 12 thereon, with each package site 12 including at least one die attach region 30 plus at least one and typically a plurality of electrically conductive terminal pads 40 associated with or surrounding each die attach region 30. For instance, a plurality of die attach regions 30 and terminal pads 40 can be arrayed on the temporary support member 20 at package sites 12, with multiple terminal pads 40 surrounding each die attach region 30. A given die attach region 30 can thus be defined as a predetermined area within a particular package site 12 within which an integrated circuit chip 60 can be positioned or mounted on the temporary support member 20, such that the integrated circuit chip 60 is surrounded by corresponding terminal pads 40 of the package site 12 during the assembly or manufacture of packages 100 in accordance with embodiments of the present disclosure. Dashed lines Y in FIG. 4 generally illustrate a manner in which boundaries of each package site 12, and hence each package 100, can be defined.

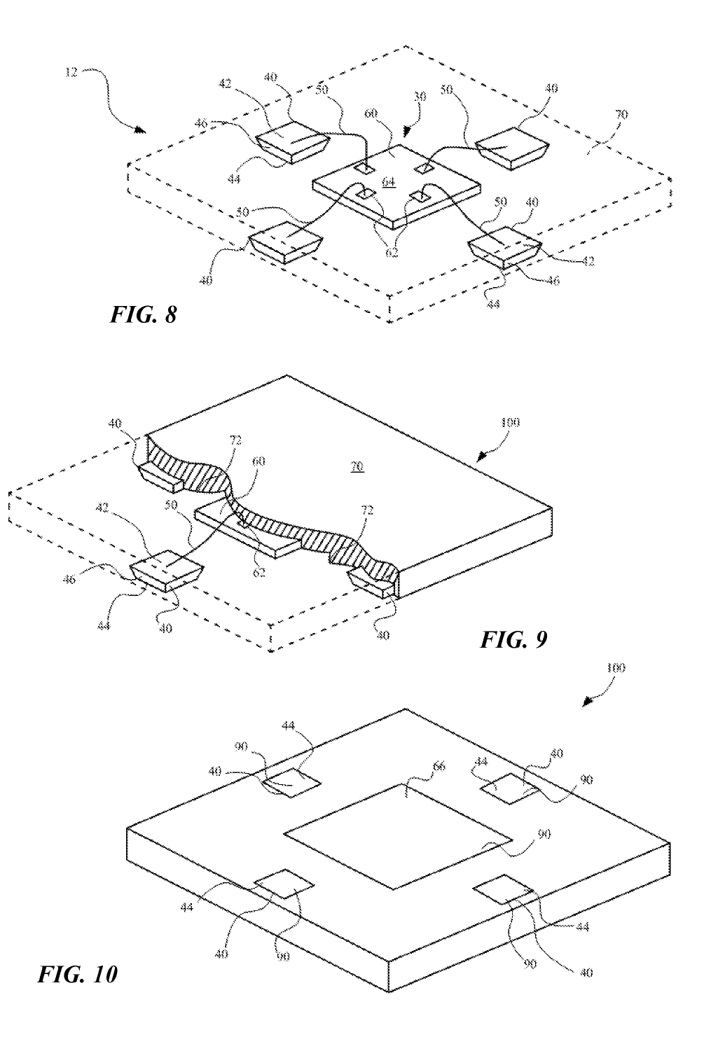

For purpose of simplicity and to aid understanding, the representative embodiment shown in FIGS. 6 and 7 is significantly simplified over a typical embodiment, in that each package site 12 is shown as including only four terminal pads 40 surrounding each die attach region 30; and the integrated circuit chip 60 corresponding to the package site 12 of FIG. 8 is shown as having an upper surface 64 that includes only four input/output junctions 62, which are wire bonded to the four terminal pads 40 of the package site's die attach region 30. Individuals having ordinary skill in the relevant art will understand that in a typical embodiment, the integrated circuit chip 60 can include many input/output junctions 62, e.g., potentially hundreds of input/output junctions 62. Correspondingly, many terminal pads 40 are present surrounding each die attach region 30, e.g., potentially hundreds of terminal pads 40 are present. Such terminal pads 40 are typically present in multiple rows, including an innermost row closest to the die attach region 30, an outermost row of terminal pads 40 most distant from the die attach region 30, and potentially one or multiple intermediate rows between the innermost row and the outermost row of terminal pads 40. Moreover, some or all terminal pads 40 can be smaller or larger relative to the die attach region 30 depicted in this representative embodiment.

For any given lead carrier 10, the terminal pads 40 of its package sites 12 can exhibit various geometries and locations, but the terminal pads 40 are typically formed of similar or identical material. In particular, the terminal pads 40 are typically formed of a sinterable/sintered electrically conductive material. According to a several embodiments, the terminal pads 40 include or begin as a powder of at least one electrically conductive material, for instance, silver, mixed with a suspension component, which includes an organic fluid, or combination of organic fluids, having between 5 and 25 weight percent of the electrically conductive material therein. This suspension component generally acts to give the silver powder a consistency of paste or other flowable and thixotropic characteristics, with viscosity ranging from 20 Pas to 50,000 Pas, so that the silver powder can best be handled, manoeuvred, and/or flowed to exhibit the desired geometry for the pads 40.

The suspension component including the silver powder are selectively applied to sites on the temporary support member 20 in a manner that defines the terminal pads 40, as further detailed with reference to FIGS. 12-14 below. After application to intended sites on the temporary support member 20, the mixture of the suspension component and the silver powder and/or other electrically conductive metal powder is heated to a sintering temperature. As a result of such heating, the suspension component boils into a gas and is evacuated from the lead frame 10; and the metal powder is sintered into a unitary mass having the shape desired for the terminal pads 40.

The temporary support member 20 is configured to have thermal characteristics such that it maintains its flexibility and desired degree of strength and other properties at least up to the sintering temperature of the electrically conductive material forming the pads 40. Typically, this sintering temperature is approaching the melting point for the metal powder that is sintered into the pads 40.

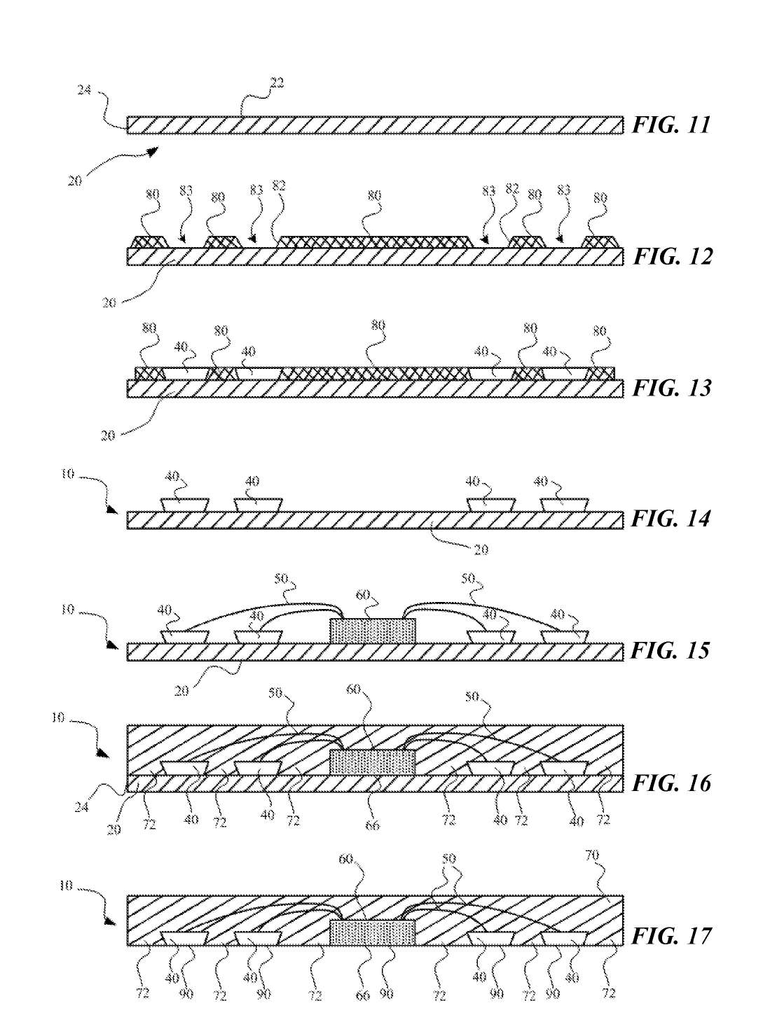

More particularly, with reference to FIGS. 11-14, a cross-sectional illustration of the lead carrier 10 is presented showing representative sequential steps for forming the terminal pads 40 in accordance with an embodiment of the present disclosure. Initially, the temporary support member 20 is provided, as shown in FIG. 11. Next, as shown in FIG. 12, a temporary form material 80 is initially placed, disposed, or deposited upon the temporary support member 20 in accordance with a predetermined pattern having openings or apertures therein corresponding to positions or locations at which the terminal pads 40 are to be formed. The temporary form material 80 includes or is formed of a long high molecular weight polymer, chosen to evaporate or burn away completely, leaving no residue or ash. This form material 80 can be printed onto the lead carrier 10, or can be etched into a continuous material that is pre-placed upon the temporary support member 20, or otherwise formed depending upon embodiment details.

Lateral surfaces 82 of the temporary form material 80 define the boundaries or edges of voids 83 between areas occupied by the temporary form material 80. These voids 83 are filled with the mixture of the metal powder and suspension component by flowing this mixture into the voids 83, in the manner indicated in FIG. 13. When the sintering process occurs and the temporary support member 20 as well as the temporary form material 80 and the metal powder and suspension mixture are heated to the sintering temperature of the mixture, not only is the metal powder sintered and the suspension component volatilized and removed, but the temporary form material 80 is also volatilized and removed from the package sites 12 across the lead carrier 10. Thus, after sintering only the terminal pads 40 formed of the sintered metal material remain upon the temporary support member 20, as shown in FIG. 14.

A terminal pad 40 can have a variety of different sizes and geometries. In various embodiments, the terminal pad 40 includes a substantially planar top side 42, as shown in FIGS. 8 and 9, disposed opposite a substantially bottom side 44 as shown in FIG. 8-10. Typically, the upper side 42 of each terminal pad 40 resides in a common plane. However, in some embodiments the upper sides 42 of different terminal pads 40 have differing heights, and these sides 42 can be in a form other than completely planar.

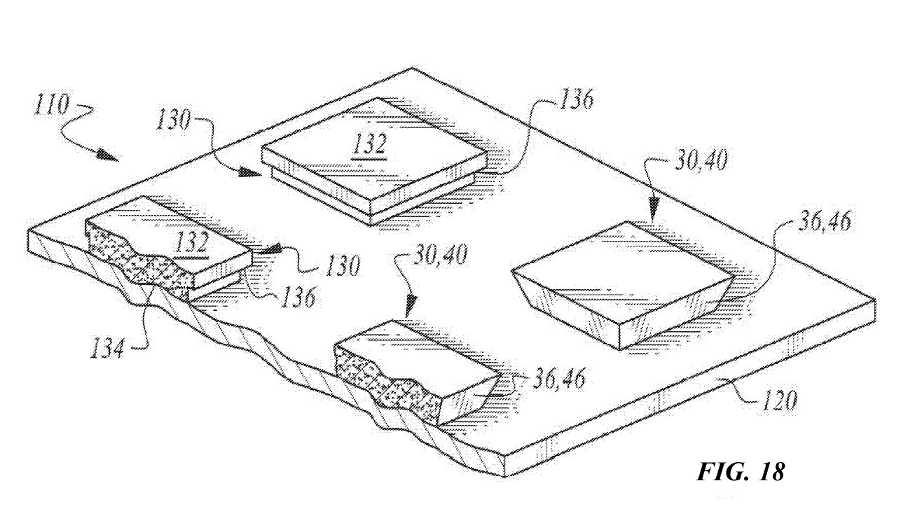

An edge 46 of the terminal pad 40 defines a perimeter or peripheral shape of the terminal pad 40. This edge 46 is typically not oriented within a plane perpendicular to the temporary support member 20, but has a taper or otherwise is configured to be contoured so that at least a partial undercut or overhang exists with an upper extent of each edge 46 (i.e., further away from the top surface 22 of the temporary support member 20) overhanging a lower extent of each edge 46 (closer to or at the top surface 22 of the temporary support member 20). This overhang relationship can be continuous, such as by tapering the edge 46 in the manner shown in FIGS. 13 and 14. In alternative forms such as shown in FIG. 18, an edge 46 can have other contours such as a stepped contour, and still provide some form of undercut or overhanging profile along its height. In other embodiments, so long as at least some portion of the edge 46 corresponding to an upper extent thereof overhangs a portion of the edge 46 closer to a lower extent of the edge 46, a form of overhang is provided. While each edge 46 of each terminal pad 40 in the representative embodiment shown has an overhanging contour, in some embodiments only some of the edges 46 of some or each terminal pad 40 have such an overhanging contour.

During terminal pad 40 formation, the bottom side 44 of each terminal pad 40 resides or rests upon the top surface 22 of the temporary support member 20, in a manner shown in FIG. 7. As further detailed below, the bottom side 44 of each terminal pad 40 forms a surface mount joint 90 that remains exposed on the underside of the package 100 that contains the terminal pad 40, in the manner shown in FIG. 10.

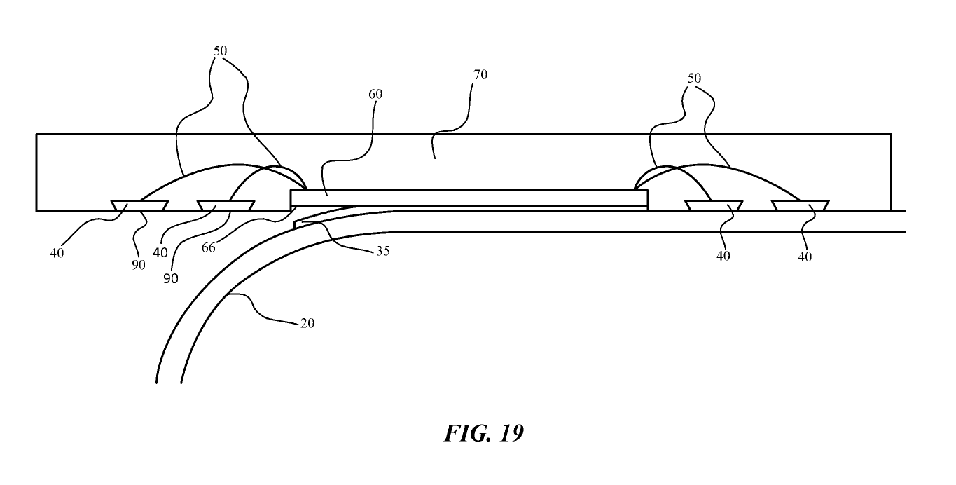

After formation of the terminal pads 40, integrated circuit chips 60 can be positioned or mounted on the die attach regions 30 of the temporary support member 20 across the package sites 12 corresponding thereto, in a manner shown in FIG. 15. With respect to mounting the integrated circuit chips 60 on the die attach regions 30, as indicated in FIG. 19 each integrated circuit chip 60 includes a base 66 defining a lower portion thereof. In several embodiments, the base 66 of the integrated circuit chip 60 is treated or coated with one or more materials such as a thin layer of gold, platinum, silver, and/or alloys of such materials. In preparation for positioning or mounting integrated circuit chips 60 on the temporary support member 20, a temporary adhesive layer 35, which includes or is a conventional die attach material, chosen for low cost and a low adhesion to the treated base 66 of integrated circuit chip 60 relative to its adhesion to top surface 22 of temporary support member 20, is applied to die attach regions 30 across temporary support member 20. The treated base 66 of the integrated circuit chip 60 is placed in contact with a temporary adhesive layer 35, which is in contact with the die attach region 30 on the temporary support member 20. Thus, the temporary adhesive layer 35 serves as an intermediary layer between top surface 22 of the temporary support member 20 and the treated base 66 of the integrated circuit chip 60. As further detailed below, the temporary adhesive layer 30 aids clean separation of the temporary support member 20 from the treated base 66 of the integrated circuit chip 60. Each integrated circuit chip 60 can have a corresponding temporary adhesive layer 35 applied to its treated base 66 prior to mounting of the integrated circuit chip 60 on a given die attach region 30 of the temporary support member 20.

Once the integrated circuit chips 60 have been positioned or mounted on the die attach regions 30, as shown in FIG. 8 the plurality of input/output junctions 62 on the upper surface 64 of each integrated circuit chip 60 can be selectively electrically coupled or linked to the terminal pads 40 by way of wire bonds 50, in a manner shown in FIGS. 8, 9, and 15, as readily understood by individuals having ordinary skill in the relevant art. For any given integrated circuit chip 60, one wire bond 50 is typically terminated between each input/output junction 62 on the integrated chip 60 and a surrounding terminal pad 40. Thus, each wire bond 50 has a chip end opposite a terminal pad end.

After wire bonds 50 have been formed between the input/output junctions 62 of the integrated circuit chips 62 and their corresponding terminal pads 40, a molding process is performed during which mold compound 70 is flowed over the entire top surface 22 of the lead carrier 10. The mold compound 70 is typically of a variety which will melt at a temperature and while held at the same temperature, will polymerize and solidify after a period of time ranging from 20 seconds to 200 seconds. The mold compound 70 is formed of a conventional non-conductive or substantially non-conductive material, such that the terminal pads 40 are electrically isolated from each other.

The mold compound completely encapsulates each of the terminal pads 40, wire bonds 50, and integrated circuit chips 60 across the package sites 12 of the lead carrier 10 above the top surface 22 of the temporary support member 20, in a manner indicated in FIG. 16. More particularly, the mold compound 70 molds against the top surface 22 of the temporary support member 20, and encapsulates structures above the top surface 22 of the temporary support member 20 that are exposed to the mold compound 70. The mold compound 70 does not encapsulate structures that directly face and which are adjacent to the temporary support member 20. Thus, the bottom sides 44 of each terminal pad 40 (which for any given package 100 form surface mount joints 90 thereof, as shown in FIG. 10), the temporary adhesive layer 35 in contact with the treated base 66 of each integrated circuit chip 60, and the treated base 66 of each integrated circuit chip 60 (which also remains an exposed part of any given package 100, as shown in FIG. 10, and can thus also be defined as or form a surface mount joint 90 that remains exposed on the underside of the package 100, as also shown in FIG. 10) are not encapsulated by the mold compound 70 during the molding process.

After the mold compound 70 has hardened, the hardened mold compound 70 and the structures encapsulated therein plus the temporary support member 20 can be defined as an assembled lead carrier 10. The temporary support member 20 can be peeled away from assembled lead carrier 10 in a manner indicated in FIG. 19 to yield a stand-alone molded lead carrier 10′ in a manner shown in FIG. 17. The stand-alone molded lead carrier 10′ includes a strip, array, or matrix of package sites 12 in which adjacent and adjoining package sites are structurally interconnected to each other by way of the hardened mold compound 70.

Individual packages 100 can be formed from the stand-alone molded lead carrier 10′ by way of cutting or sawing the stand-alone molded lead carrier 10′ along package site borders or boundaries (e.g., corresponding to dashed lines Y shown in FIG. 7). As shown in FIG. 10, each package 100 includes a top 102, an opposing bottom 104, and perimeter sides 106. For any given package 100, surface mount joints 90 corresponding to the terminal pads 40 of the package 100, and the treated base 66 of the integrated circuit chip 60 of the package 100, remain exposed on the bottom 104 of the package 100, as also shown in FIG. 10.

Beneficially, lead carriers 100 fabricated in accordance with embodiments of the present disclosure exclude shorting structures 6 and tie bars 2 found in prior art lead frames 1. Thus, packages 100 manufactured in accordance with embodiments of the present disclosure exclude tie bars 3 extending therein, the packages 100 need not have any unnecessary electrically conductive material extending therein or extending therefrom, in contrast to prior art QFN packages P. Packages 100 in accordance with embodiments of the present disclosure thus do not suffer from the same parasitic capacitance problems as prior art QFN packages P, and are suitable for use with integrated circuit chips 60 that operate at higher frequencies.

As indicated above, the edges of the terminal pads 40 have an overhanging or undercut profile. During the molding process, the mold compound 70 flows between each terminal pad 40 and its neighbouring terminal pads 40 and its corresponding integrated circuit chip 60. Due to the overhanging or undercut profile of the edges 46 of the terminal pads 40, the mold compound 70 effectively forms interlock structures or interlocks 72 that inherently structurally engage or mechanically self-engage the mold compound 70 with the edges 46 of the terminal pads 40 in a manner shown in FIG. 16. More particularly, edges or borders of the interlocks 72 interface with the undercut or overhanging edges 46 of the terminal pads in a manner that resists downward vertical displacement of the terminal pads 40 away from the hardened mold compound 70. The interlocks 72 thus tend to retain or hold the terminal pads 40 in position within the mold compound 70, and aid in keeping the terminal pads 40 from becoming detached from the wire bonds 50. Such detachment propensity is first resisted when the temporary support member 20 is removed or peeled from the lead carrier 10, and again resisted when the package 100 is in use and might experience shock loads that might otherwise detach the terminal pads 40 from the wire bonds 50 and/or the package 100. These interlocks 72 can have a variety of different shapes as defined in association with or by way of the contoured edges 46 of the pads 40. The shape(s) of the interlocks 72 are originally based on or determined by the contour of the lateral surfaces 82 of the temporary form material 80, as indicated in FIGS. 12 and 13.

With reference to FIG. 19, the temporary adhesive layer 35 that resides between the base 66 of each integrated circuit chip 60 and the temporary support member 20 includes one or more materials such as a commercial epoxy die attach material, for example Hysol® QMI538NB. The base 66 of each integrated circuit chip 60 can be treated or coated with a material that is resistant to forming a strong bond with the adhesive layer 35. Such treatment can protect the base 66 of the integrated circuit chip 60 from oxidation, and can provide a highly solderable surface. As indicated above, the base 66 can be treated or coated with a thin layer of gold, platinum, silver, or alloys of such materials. The adhesive layer 35 is chosen to form a two time to ten times stronger adhesive bond with the top surface 22 of the temporary support member 20 than with the surface of the treated base 66 of integrated circuit chip 60, to facilitate ease of removing the temporary support member 20 following the molding process that encapsulates the integrated circuit chips 60, terminal pads 40, and wire bonds 50 in the mold compound 70.

In view of the foregoing, when the temporary support member 20 is removed from the assembled lead carrier 10, the temporary support member 20 separates cleanly from the mold compound 70 and the surface mount joints 90 of each terminal pad 40, but the temporary adhesive layer 35 remains attached to the temporary support member 20 and is removed cleanly from the base 66 of each integrated circuit chip 60. Thus, in any given package 100, the surface mount joints 90 of each terminal pad 40 and the base 66 of each integrated circuit chip 60 remain exposed after removal of the temporary support member 20, as indicated in FIG. 10. The surface mount joints 90 of the terminal pads 40, and the treated bases 66 of the integrated circuit chip 60 can be surface mounted, for instance, to a surface mount board by a conventional surface mount soldering process.

With reference to FIG. 18, details of an alternative lead carrier 110 are shown. In this alternative lead carrier 110, a temporary support member 120 has alternative pads 130 residing or resting thereon. These alternative pads 130 include a top side 132 opposite a bottom side 134, with a stepped edge 136 thereon. This stepped edge 136 is an alternative edge to the edges 46 provided on the terminal pads 40 described above. Such a stepped edge 136 still provides a form of interlocking with the mold compound 70 to beneficially hold the pads 40 within the entire package 100.

The description herein is provided to reveal particular representative embodiments in accordance with the present disclosure. It will be apparent that various modifications can be made to the embodiments described herein without departing from the scope of the present disclosure, or the claims included herewith.

1. A lead carrier for assembling packaged semiconductor die encapsulated in a mold compound, the lead carrier comprising:
a continuous sheet of mold compound having a top side and an opposing back side, the continuous sheet of mold compound comprising an array of package sites, each package site corresponding to a semiconductor die package, each package site comprising:
a semiconductor die having a top side and an opposing treated base that is exposed at the back side of the continuous sheet of mold compound;
a set of terminal pads, each terminal pad having a top side and an opposing back side that is exposed at the back side of the continuous sheet of mold compound;
a plurality of wire bonds formed between a set of input/output junctions on the top side of the semiconductor die and the top side of each terminal pad within the set of terminal pads; and
hardened mold compound that encapsulates the semiconductor die, the set of terminal pads, and the plurality of wire bonds.

2. The lead carrier of claim 1, wherein each package site excludes a die attach pad to which the semiconductor die is fixed.

3. The lead carrier of claim 1, wherein the treated base of the semiconductor die comprises a coating of gold, platinum, silver, and/or an alloy thereof applied to a back side of the semiconductor die.

4. The lead carrier of claim 1, wherein at each package site the exposed treated base of the semiconductor die and the exposed back side of each terminal pad define surface mount junctions for the semiconductor die package corresponding to the package site.

5. The lead carrier of claim 1, further comprising a temporary support layer that supports the continuous sheet of mold compound, the temporary support layer having a top surface against which the bottom surface of the continuous sheet of mold compound resides.

6. The lead carrier of claim 5, further comprising at each package site a temporary adhesive layer disposed between the treated base of the semiconductor die and the top surface of the temporary support layer, wherein the temporary adhesive layer is removable from the treated base of the semiconductor die.

7. The lead carrier of claim 6, wherein the temporary adhesive layer comprises a conventional die attach material having a higher level of adhesion to the top surface of the temporary support layer than to the treated base of the semiconductor die.

8. The lead carrier of claim 6, wherein each terminal pad comprises a sintered material adhered to the top surface of the temporary support layer.

9. The lead carrier of claim 8, wherein each terminal pad has a height and a peripheral border, and wherein the peripheral border of at least one terminal pad includes an overhang region that causes an upper portion of the terminal bad to laterally extend beyond a lower portion of the terminal pad, and wherein the overhang region interlocks with the hardened mold compound to resist downward vertical displacement of the terminal pad from the hardened mold compound.

10. The lead carrier of claim 9, wherein at each package site a level of adhesion of each terminal pad to the top surface of the temporary support layer is less than a level of adhesion of the peripheral border of the terminal pad to the hardened mold compound.

11. The lead carrier of claim 10, wherein the temporary support layer is peelably removable from the continuous sheet of mold compound.

12. A semiconductor die package having a top side and an opposing back side, the semiconductor die package comprising:
a semiconductor die having a top side and an opposing treated base that is exposed at the back side of the semiconductor die package;
a set of terminal pads, each terminal pad having a top side and a back side that is exposed at the back side of the semiconductor die package;
a plurality of wire bonds formed between a set of input/output junction on a top surface of the semiconductor die and the top surface of each terminal pad within the set of terminal pads; and
hardened mold compound that encapsulates the semiconductor die, the set of terminal pads, and the plurality of wire bonds,
wherein the semiconductor die package excludes a die attach pad to which the semiconductor die of the package site is fixed.

13. The semiconductor die package of claim 12, wherein the semiconductor die package is a Quad Flat No Lead (QFN) package.

14. The semiconductor die package of claim 12, wherein the treated base of the semiconductor die comprises a coating of gold, platinum, silver, and/or an alloy thereof applied to a back side of the semiconductor die.

15. The semiconductor die package of claim 12, wherein each terminal pad has a height and a peripheral border, and wherein the peripheral border of at least one terminal pad includes an overhang region that causes an upper portion of the terminal bad to laterally extend beyond a lower portion of the terminal pad, and wherein the overhang region interlocks with the hardened mold compound to resist downward vertical displacement of the terminal pad from the hardened mold compound.

16. A method for fabricating packaged semiconductor die by way of a lead carrier, the method comprising:
providing a temporary support layer having a top side on which semiconductor die packages are to be assembled at corresponding package sites, each package site comprising a predetermined fractional area of the temporary support layer on the top side thereof, and having a die attach region therein;
disposing a paste carrying a sinterable metal in a predetermined pattern on the top side of the temporary support layer;
sintering the paste to form a set of terminal pads at each package site, each terminal pad having a top side and an opposing back side adhered to the temporary support layer, wherein the set of terminal pads is disposed outside of the die attach region of the package site in accordance with the predetermined pattern of the paste;
at each package site, mounting a semiconductor die to the die attach region of the package site by disposing a temporary adhesive layer on the top surface of the temporary support layer in the die attach region and disposing a treated base of the semiconductor die on the temporary support layer such that the temporary adhesive layer is interposed between the treated base of the semiconductor die and the top surface of the temporary support layer;
at each package site, selectively forming a plurality of wire bonds between a set of input/output terminals of a top side of the semiconductor die and top side of each terminal pad within the set of terminal pads;
forming a continuous sheet of molded package sites by applying a mold compound across the package sites such that the semiconductor die, the set of terminal pads, and the plurality of wire bonds formed at each package site are encapsulated in the mold compound;
peeling the temporary support layer away from the continuous sheet of molded package sites and removing the temporary adhesive layers from the treated bases of the semiconductor die of the continuous sheet of molded package sites; and
separating individual package sites within the continuous sheet of molded package sites from each other to thereby form individual packages that each contain a selected semiconductor die and a selected set of terminal pads electrically coupled thereto, wherein each package includes a top side and an opposing bottom side at which the treated base of the selected semiconductor die and the bottom side of each terminal pad within the selected set of terminal pads of the package are exposed to thereby form surface mount junctions of the package.

17. The method of claim 16, further comprising at each package site avoiding providing a die attach pad on which the semiconductor die of the package site is fixable.

18. The method of claim 16, wherein at each package site, the temporary adhesive layer comprises a conventional die attach material having a higher level of adhesion to the top surface of the temporary support layer than to the treated base of the semiconductor die disposed at the package site.
